(19) United States
(12) Patent Application Publication
(10) Pub. No.: US 2020/0098700 A1
(43) Pub. Date: Mar. 26, 2020

(54) SEMICONDUCTOR PACKAGE DEVICE AND METHOD OF MANUFACTURING THE SAME

(71) Applicant: Advanced Semiconductor Engineering, Inc., Kaohsiung (TW)

(72) Inventors: Jr-Wei LIN, Kaohsiung (TW); Chien-Feng CHAN, Kaohsiung (TW)

(73) Assignee: Advanced Semiconductor Engineering, Inc., Kaohsiung (TW)

(21) Appl. No.: 16/138,937

(22) Filed: Sep. 21, 2018

(51) Int. Cl. H01L 23/00; H01L 23/552; H01L 23/31; H01L 23/48; H01L 21/56

(52) U.S. Cl. CPC H01L 23/562; H01L 23/552; H01L 21/56; H01L 23/481; H01L 23/3121

(57) ABSTRACT

A semiconductor package device includes a substrate, a sealant, a trench, a spacer and a conductive material. The substrate includes a first surface, a second surface opposite the first surface, and a lateral surface extending from the first surface to the second surface. The sealant is disposed on the first surface of the substrate and includes a first surface and a second surface opposite the first surface. The trench passes through the sealant and includes a first portion adjacent to the first surface of the sealant and a second portion between the first portion and the substrate. A width of the first portion is greater than a width of the second portion. The spacer is disposed in the trench and in contact with the sealant. The conductive material is disposed in the trench and encapsulates the spacer.

### BACKGROUND

### 1. Technical Field

The present disclosure relates generally to a semiconductor package device, and more particularly, the present disclosure relates to a semiconductor package device including a spacer.

### 2. Description of the Related Art

In a semiconductor package device, a shielding wall (e.g., compartment shielding (CPS)) can be implemented to avoid electromagnetic interference between different electronic components. In implementing a CPS structure, a trench is formed to penetrate a molding compound (or a sealant) of the semiconductor package device, and a conductive material is filled in the trench and grounded to form a shielding wall.

However, the conductive material currently used to fill the trench has a coefficient of thermal expansion (CTE) much greater than a CTE of the molding compound (for example, two times greater), such that warpage may occur during subsequent operations such as baking, reflowing or cooling. Weight pressing may be used to suppress the warpage but would involve extra tools, operations and cost.

### SUMMARY

In one aspect, according to some embodiments, a semiconductor package device includes a substrate, a sealant, a trench, a spacer and a conductive material. The substrate includes a first surface, a second surface opposite the first surface, and a lateral surface extending from the first surface to the second surface. The sealant is disposed on the first surface of the substrate and includes a first surface and a second surface opposite the first surface. The trench passes through the sealant and includes a first portion adjacent to the first surface of the sealant and a second portion between the first portion and the substrate. A width of the first portion is greater than a width of the second portion. The spacer is disposed in the trench and in contact with the sealant. The conductive material is disposed in the trench and encapsulates the spacer.

In another aspect, according to some embodiments, a semiconductor package device includes a substrate, a sealant, a trench, a spacer and a conductive material. The substrate includes a first surface, a second surface and a lateral surface extending from the first surface to the second surface. The sealant encapsulates the first surface of the substrate and includes a first surface and a second surface opposite the first surface. The trench passes through the sealant. The spacer is disposed in the trench and in contact with the sealant. The conductive material is filled in the trench and encapsulates a top surface of the spacer.

In yet another aspect, according to some embodiments, a method of manufacturing a semiconductor package device includes providing a substrate, providing a sealant on the substrate, removing a portion of the sealant to form a trench, disposing a spacer in the trench and in contact with the sealant, and forming a conductive material in the trench. The conductive material encapsulates the spacer.

### BRIEF DESCRIPTION OF THE DRAWINGS

Aspects of the present disclosure are best understood from the following detailed description when read with the accompanying drawings. It is noted that various features may not be drawn to scale, and, in the drawings, the dimensions of the depicted features may be arbitrarily increased or reduced for clarity of discussion.

FIG. 1A illustrates a cross-sectional view of a semiconductor package device in accordance with some embodiments of the present disclosure.

FIG. 1B illustrates a top view of a semiconductor package device in accordance with some embodiments of the present disclosure.

FIG. 1C illustrates a cross-sectional view of a semiconductor package device in accordance with some embodiments of the present disclosure.

FIG. 2A illustrates a cross-sectional view of a semiconductor package device in accordance with some embodiments of the present disclosure.

FIG. 2B illustrates a top view of a semiconductor package device in accordance with some embodiments of the present disclosure.

FIG. 2C illustrates a cross-sectional view of a spacer of a semiconductor package device in accordance with some embodiments of the present disclosure.

FIG. 3A, FIG. 3B, FIG. 3C, FIG. 3D and FIG. 3E are cross-sectional views of a semiconductor package device at various stages of fabrication.

Common reference numerals are used throughout the drawings and the detailed description to indicate the same or similar elements. The present disclosure will be more readily understood from the following detailed description taken in conjunction with the accompanying drawings.

### DETAILED DESCRIPTION

According to some embodiments of the present disclosure, during implementation of a CPS structure in a semiconductor package device, disposing a spacer with a CTE lower than a CTE of a conductive material within a trench of a sealant (or a molding compound/encapsulant) of the semiconductor package device, and filling the trench and encapsulating the spacer with the conductive material can reduce or suppress warpage of the semiconductor package device.

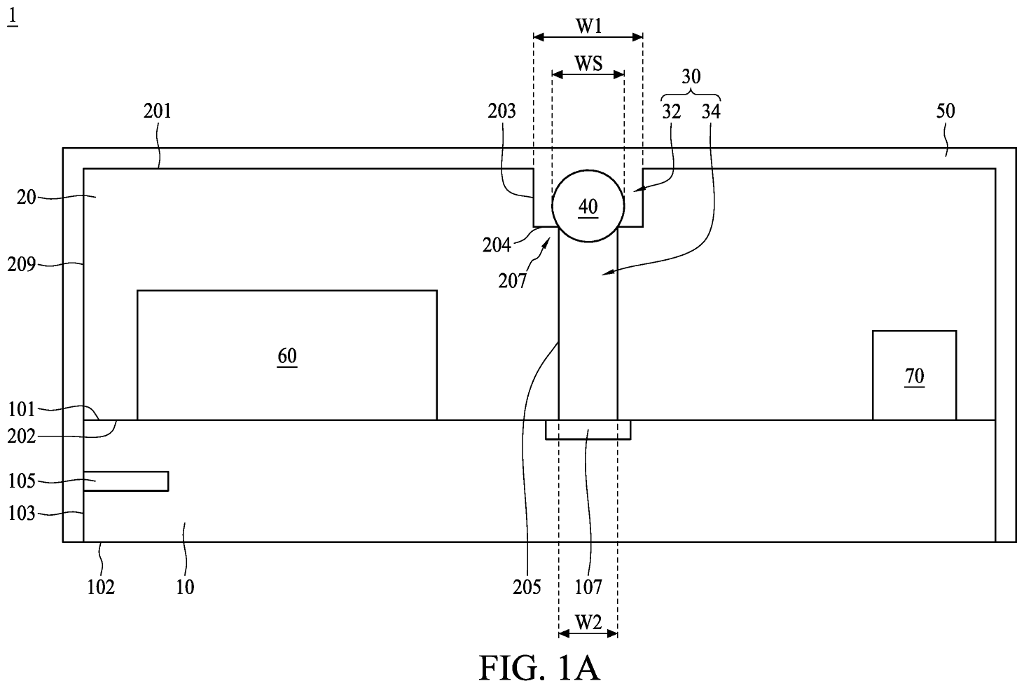

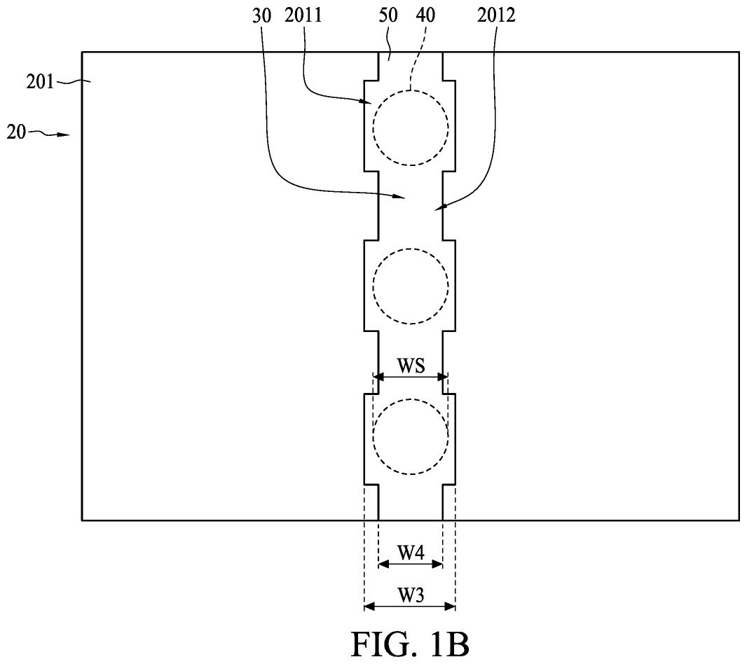

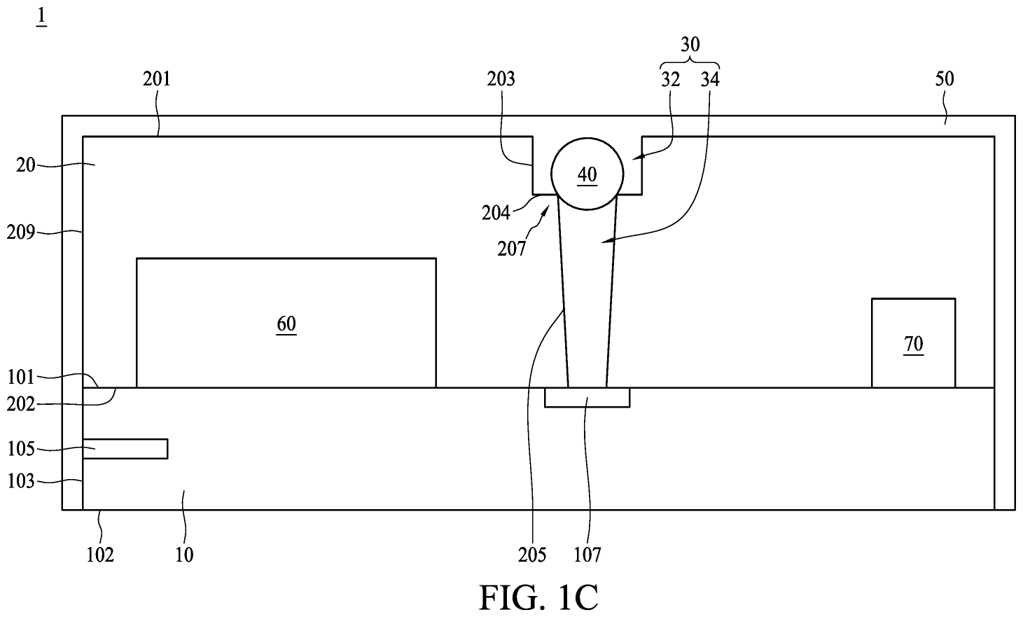

FIG. 1A illustrates a cross-sectional view of a semiconductor package device 1 in accordance with some embodiments of the present disclosure. The semiconductor package device 1 includes a substrate 10, a sealant (or encapsulant) 20, a trench (or space/cavity) 30, a spacer 40, a conductive material 50 and electronic components 60 and 70.

The substrate includes a surface 101, a surface 102 opposite the surface 101, and a surface 103 extending from the surface 101 to the surface 102. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a redistribution layer (RDL) or a grounding element. In some embodiments, the grounding element (e.g., the conductive trace 105) is a via exposed from a lateral surface of the substrate 10. In some embodiments, the grounding element is a metal layer exposed from a lateral surface of the substrate 10. In some embodiments, the grounding element is a metal trace exposed from a lateral surface of the substrate 10. In some embodiments, the surface 101 of the substrate 10 is referred to as a top surface or a first surface and the surface 102 of the substrate 10 is referred to as a bottom surface or a second surface.

The electronic component 60 is disposed on the surface 101 of the substrate 10. The electronic component 70 is disposed on the surface 101 of the substrate 10 and spaced apart from the electronic component 60 by the trench 30. The electronic component 60 may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The electronic component 70 may have similar features as the electronic component 60.

The sealant 20 is disposed on the surface 101 of the substrate 10. The sealant 20 includes a surface 201 and a surface 202 opposite the surface 201. The sealant 20 encapsulates the surface 101 of the substrate 10 and the electronic components 60 and 70. In some embodiments, the sealant 20 includes an epoxy resin having fillers, a molding compound (e.g., an epoxy molding compound or other molding compound), a polyimide, a phenolic compound or material, a material with a silicone dispersed therein, or a combination thereof.

The trench 30 passes through or penetrates through the sealant 20. For example, the trench 30 divides the sealant 20 into a first portion covering the electronic component 60 and a second portion covering the electronic component 70. The trench 30 includes a portion 32 and a portion 34. The portion 32 is adjacent to the surface 201 of the sealant 20. The portion 34 is between the portion 32 and the substrate 10. For example, the portion 32 is above the portion 34. A width W1 of the portion 32 is greater than a width W2 of the portion 34. The trench 30 may taper from the surface 201 to the surface 202 of the sealant 20. The substrate 10 includes a stop layer 107 on or adjacent to the surface 101 of the substrate 10. The stop layer 107 is exposed from the trench 30. A top surface of the stop layer 107 may have a recess corresponding to the portion 34 of the trench 30. The recess may be resulted during forming the trench 30 by operations such as a laser or etching operation.

As shown in FIG. 1A, the trench 30 is defined by surfaces 203, 204 and 205 of the sealant 20. The surface 203 and/or 205 may be perpendicular with respect to the surface 201 of the sealant 20. The surface 203 and/or 205 may be slanted or inclined with respect to the surface 201 of the sealant 20 (for example, as shown in FIG. 1C, wherein the surface 205 is slanted with respect to the surface 201 of the sealant 20). The portion 32 and/or the portion 34 of the trench 30 may have a tapered shape. The portion 32 and/or the portion 34 of the trench 30 may taper in a direction from the surface 201 toward the surface 202 of the sealant 20. The surface 204 may be parallel with respect to the surface 201 of the sealant 20. The surface 204 may be inclined or slanted with respect to the surface 201 of the sealant 20. In some embodiments, a slanted surface 204 may help guide the spacer 40 during disposal of the spacer 40 in the trench 30 when manufacturing the semiconductor package device 1. A step portion 207 of the sealant 20 is defined by the surface 204 and the surface 205. The step portion 207 is between the portion 32 and the portion 34 of the trench 30. The step portion 207 divides the portion 32 and the portion 34 of the trench 30. The step portion 207 may be ladder-shaped. The step portion 207 may have an angle greater than or equal to 90° defined by the surface 204 and the surface 205.

The spacer 40 is disposed in the trench 30. The spacer 40 is in contact with the sealant 20. The spacer 40 is in contact with or engaged with the step portion 207 of the sealant 20. A portion of the spacer 40 is in the portion 34 of the trench 30. At least half of the spacer 40 is in the portion 32 of the trench 30. A width WS of the spacer 40 is greater than a width W2 of the portion 34 of the trench 30. In some embodiments, the spacer 40 may be in contact with the surface 203 and/or the surface 205 of the sealant 20. In some embodiments, the spacer 40 reduces warpage of the semiconductor package device 1 by providing a support force to the sealant 20 through the engagement with the step portion 207 of the sealant 20.

The spacer 40 may be fully within the trench 30. The spacer 40 may be fully surrounded by the sealant 20. A tip or a surface of the spacer 40 may be lower than or equal to the surface 201 of the sealant 20. A top surface of the spacer 40 may be coplanar with the surface 201 of the sealant 20. In the embodiment shown in FIG. 1A, the spacer 40 has a ball or a circular shape. However, the shape of the spacer 40 is not limited. The spacer 40 may have a square, a tapered or any suitable shape. For example, the spacer 40 may taper in a direction toward the substrate 10. The spacer 40 may include a conductive material such as metal. The spacer 40 may include copper (Cu). In some embodiments, the spacer 40 may include non-conductive material.

The conductive material 50 is disposed in the trench 30. For example, the conductive material 50 fills the trench 30. The conductive material 50 encapsulates the spacer 40. The conductive material 50 encapsulates a top surface of the spacer 40. In the embodiment shown in FIG. 1A, the conductive material 50 is further disposed on the surface 201 and a surface (or a lateral surface) 209 of the sealant 20, and on the surface 103 of the substrate 10. The conductive material 50 covers the sealant 20 and the substrate 10. The conductive material 50 may provide an electromagnetic shielding function between the electronic component 60 and the electronic component 70. The conductive material 50 may include metal such as silver (Ag). The spacer 40 and the conductive material 50 may form a CPS structure. The substrate 10 includes a conductive trace 105 electrically connected to the conductive material 50. The conductive trace 105 may be grounded.

In some embodiments, a coefficient of thermal expansion (CTE) of the conductive material 50 is greater than a CTE of the sealant 20. For example, the CTE of the conductive material 50 may be in a range between about 45 ppm/° C. and about 65 ppm/° C. The CTE of the conductive material 50 may be about 54 ppm/° C. The CTE of the sealant 20 may be in a range between about 5 ppm/° C. and about 15 ppm/° C. The CTE of the sealant 20 may be about 9 ppm/° C. During temperature cycles in manufacturing of the semiconductor package device 1, the conductive material 50 may have a greater shrinkage stress than that of the sealant 20. Warpage issues may occur and a width of the trench 30 may tend to be reduced. In some embodiments, the CTE of the conductive material 50 is greater than a CTE of the spacer 40. For example, the CTE of the spacer 40 may be in a range between about 10 ppm/° C. and about 30 ppm/° C. The CTE of the spacer 40 may be about 17 ppm/° C. During temperature cycles in manufacturing of the semiconductor package device 1, the spacer 40 may have a lower shrinkage stress than that of the conductive material 50 and thus reduce the warpage. The spacer 40 may reduce the warpage through the engagement with the step portion 207 of the sealant 20.

FIG. 1B illustrates a top view of a portion of the semiconductor package device 1 of FIG. 1A. To facilitate understanding, the sealant 20, the trench 30, the spacer 40 and the conductive material 50 are selectively depicted. The spacer 40 is depicted in dashed line because it is covered by the conductive material 50. Referring to FIG. 1B, the surface 201 of the sealant 20 defines an opening 2011 and an opening 2012. For example, the openings 2011 and 2012 correspond to an outline of the trench 30 from a top view perspective. The openings 2011 and 2012 expose the trench 30. The location of the opening 2011 corresponds to that of the spacer 40. The opening 2012 is disposed adjacent to the opening 2011. The opening 2011 and the opening 2012 are connected. A width W3 of the opening 2011 is greater than a width W4 of the opening 2012. Also referring to FIG. 1A, the width W3 of the opening 2011 may be the same as the width W1 of the portion 32 of the trench 30. The width W4 of the opening 2012 may be the same as the width W2 of the portion 34 of the trench 30. As shown in FIG. 1B, the width WS of the spacer 40 is greater than the width W4 of the opening 2012, which can help fix the position of the spacer 40 during disposal of the spacer 40 within the trench 30 when manufacturing the semiconductor package device 1.

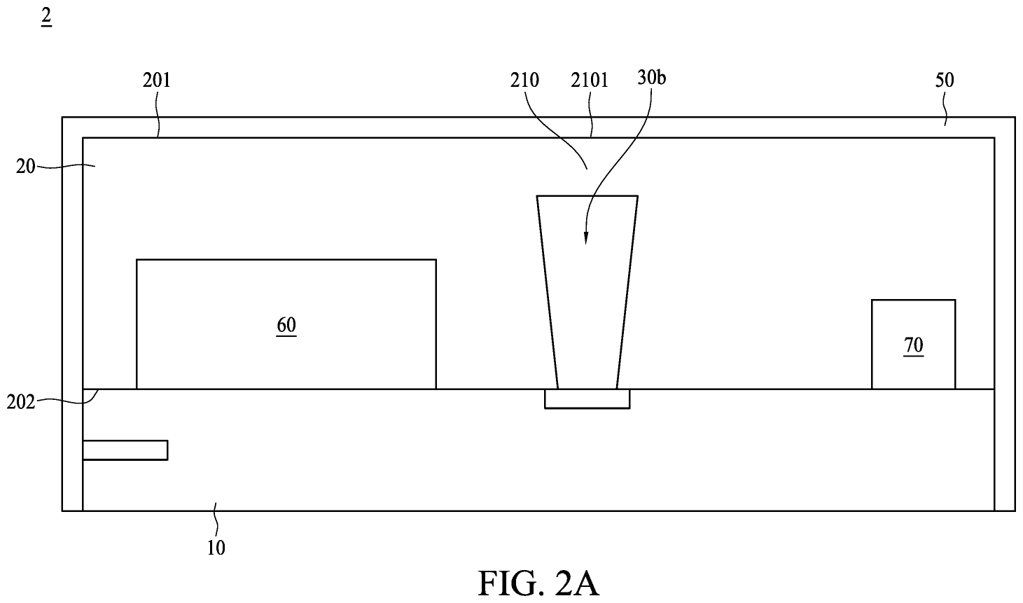

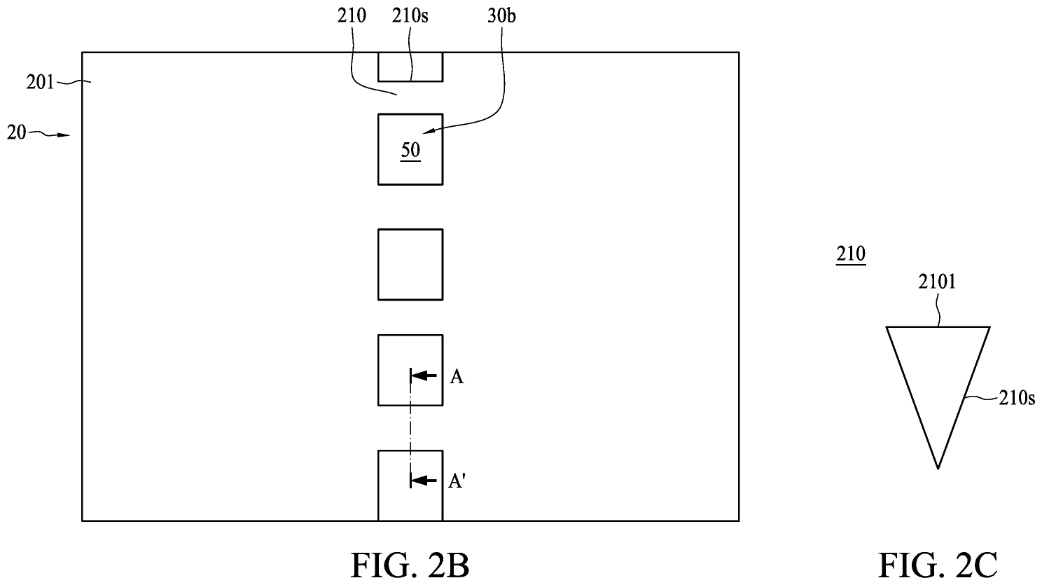

FIG. 2A illustrates a cross-sectional view of a semiconductor package device 2 in accordance with some embodiments of the present disclosure. The semiconductor package device 2 has similar properties as the semiconductor package device 1 of FIG. 1A. Some differences between the semiconductor package device 2 and the semiconductor package device 1 are described as below.

The semiconductor package device 2 has a spacer 210 and a trench 30b. The spacer 210 may be part of the sealant 20. The spacer 210 is integrally formed with the sealant 20. The spacer 210 and the sealant 20 have the same material. In other embodiments, the spacer 210 and the sealant 20 are formed of different materials. A surface 2101 of the spacer 210 is coplanar with the surface 201 of the sealant 20. The trench 30b tapers from the surface 201 of the sealant 20 to the surface 202 of the sealant 20. The trench 30b is filled with the conductive material 50 to form a CPS structure between the electronic component 60 and the electronic component 70 to avoid electromagnetic interference (EMI) between the electronic component 60 and the electronic component 70.

FIG. 2B illustrates a top view of a portion of the semiconductor package device 2 of FIG. 2A. To facilitate understanding, the sealant 20, the trench 30b, the spacer 210 and the conductive material 50 are selectively depicted. Several spacers 210 are disposed intermittently along the trench 30b. FIG. 2C illustrates an example of a cross-sectional view of the spacer 210 along the line AA′ in FIG. 2B. As shown in FIG. 2B and FIG. 2C, a side surface 210s of the spacer 210 may be slanted or inclined with respect to the surface 2101 of the spacer 210. The spacer 210 may taper in a direction from the surface 2101 towards the substrate 10.

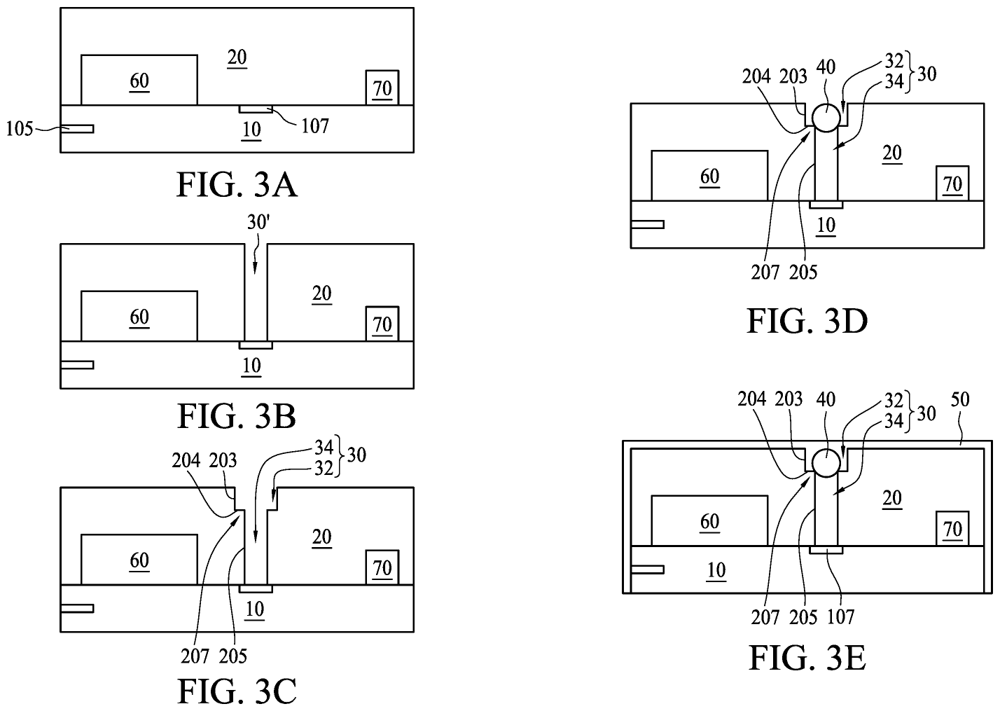

FIG. 3A, FIG. 3B, FIG. 3C, FIG. 3D and FIG. 3E are cross-sectional views of a semiconductor package device at various stages of fabrication.

Referring to FIG. 3A, a substrate 10 is provided. The substrate 10 has a conductive trace 105 and a stop layer 107. Electronic components 60 and 70 are disposed on the substrate 10. The electronic component 60 and/or the electronic component 70 may be disposed by any suitable operation such as bonding with a die attach film (DAF) or by flip-chip bonding. A sealant 20 is provided. The sealant 20 is formed on the substrate 10 to cover the electronic components 60 and 70. The sealant 20 may be formed by any suitable operation such as a molding operation.

Referring to FIG. 3B, a portion of the sealant 20 is removed to form a trench 30′. The trench 30′ may be formed by any suitable operation such as a laser operation or an etching operation. In some embodiments, at least a portion of the stop layer 107 is exposed after the formation of the trench 30′.

Referring to FIG. 3C, a portion of the sealant 20 is further removed to form a trench 30 defined by surfaces 203, 204 and 205 of the sealant 20. The trench 30 includes a portion 32 and a portion 34. A step portion 207 defined by the surface 204 and the surface 205 is formed. The step portion 207 is exposed to the trench 30. The step portion 207 (or the trench 30) may be formed by any suitable operation such as a laser operation, an etching operation or a dicing operation.

Referring to FIG. 3D, a spacer 40 is disposed in the trench 30 to be in contact with or engaged with the step portion 207. The spacer 40 may be in contact with the surface 203 and/or the surface 205 of the sealant 20. The spacer 40 may have a circular, a square, a tapered or any suitable shape. The spacer 40 may be disposed by any suitable operation such as an alignment or a pick and place operation.

Referring to FIG. 3E, a conductive material 50 is formed in the trench 30 to encapsulate the spacer 40. The conductive material 50 is formed to fill the trench 30. The conductive material 50 and the spacer 40 form a CPS structure between the electronic component 60 and the electronic component 70 to avoid electromagnetic interference (EMI) between the electronic component 60 and the electronic component 70. The conductive material 50 is formed on the sealant 20. The conductive material 50 is formed to cover the sealant 20 and the substrate 10. The conductive material 50 may be formed by any suitable operation such as screen printing, brushing, vacuum printing, sputtering, spray coating, dispensing or a combination thereof. The portion of the conductive material 50 in the trench 30 and the portion of the conductive material 50 covering the sealant 20 and the substrate 10 may be formed integrally by a vacuum printing operation.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be planar or substantially planar if a difference between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

1. A semiconductor package device, comprising:
a substrate including a first surface, a second surface opposite the first surface, and a lateral surface extending from the first surface to the second surface;
a sealant on the first surface of the substrate, the sealant including a first surface and a second surface opposite the first surface;
a trench through the sealant, the trench including a first portion adjacent to the first surface of the sealant and a second portion between the first portion and the substrate, a width of the first portion being greater than a width of the second portion;
a spacer disposed in the trench and in contact with the sealant; and
a conductive material disposed in the trench and encapsulating the spacer.

2. The semiconductor package device of claim 1, wherein the trench tapers from the first surface to the second surface of the sealant.

3. The semiconductor package device of claim 1, wherein the sealant comprises a step portion dividing the first portion of the trench and the second portion of the trench.

4. The semiconductor package device of claim 3, wherein the spacer is in contact with the step portion, and a portion of the spacer is in the second portion of the trench.

5. The semiconductor package device of claim 3, wherein at least half of the spacer is in the first portion of the trench.

6. The semiconductor package device of claim 1, wherein the first surface of the sealant defines a first opening corresponding to the spacer and a second opening adjacent to the first opening, and a width of the first opening is greater than a width of the second opening.

7. The semiconductor package device of claim 6, wherein a width of the spacer is greater than the width of the second opening.

8. The semiconductor package device of claim 1, wherein a coefficient of thermal expansion (CTE) of the conductive material is greater than a CTE of the sealant.

9. The semiconductor package device of claim 1, wherein a CTE of the conductive material is greater than a CTE of the spacer.

10. The semiconductor package device of claim 1, further comprising:
a first electronic component disposed on the first surface of the substrate;
a second electronic component disposed on the first surface of the substrate and spaced apart from the first electronic component by the trench.

11. The semiconductor package device of claim 1, wherein the conductive material is further disposed on the sealant and the lateral surface of the substrate.

12. A semiconductor package device, comprising:
a substrate including a first surface, a second surface and a lateral surface extending from the first surface to the second surface;
a sealant encapsulating the first surface of the substrate, the sealant including a first surface and a second surface opposite the first surface;
a trench through the sealant;
a spacer disposed in the trench and in contact with the sealant; and
a conductive material filled in the trench and encapsulating a top surface of the spacer.

13. The semiconductor package device of claim 12, wherein the sealant comprises a step portion dividing the trench into a first portion and a second portion, the spacer is in contact with the step portion, and a portion of the spacer is in the first portion and another portion of the spacer is in the second portion.

14. The semiconductor package device of claim 12, wherein the first surface of the sealant comprises a first opening corresponding to the spacer and a second opening adjacent to the first opening, and a width of the first opening is greater than a width of the second opening.

15. The semiconductor package device of claim 14, wherein a width of the spacer is greater than the width of the second opening.

16-20. (canceled)

21. The semiconductor package device of claim 1, wherein the trench has a sidewall, and the sidewall of the trench is slanted with respect to the first surface of the sealant.

22. The semiconductor package device of claim 1, wherein the spacer has a tip, and the tip of the spacer is disposed lower than or at a same height as the first surface of the sealant.

23. The semiconductor package device of claim 1, wherein the spacer is surrounded by the sealant.

24. The semiconductor package device of claim 1, wherein the conductive material is disposed on the first surface of the sealant and on the lateral surface of the substrate.

25. The semiconductor package device of claim 1, wherein the spacer and the sealant comprise a same material.
